(19) United States
(12) Patent Application Publication
(10) Pub. No.: US 2021/0320038 A1
(43) Pub. Date: Oct. 14, 2021

(54) SEMICONDUCTOR DEVICE PACKAGE

(71) Applicant: Advanced Semiconductor Engineering, Inc., Kaohsiung (TW)

(72) Inventors: Ting Wei HSU, Kaohsiung (TW); Pei-Jen LO, Kaohsiung (TW); Shun-Tsat TU, Kaohsiung (TW)

(73) Assignee: Advanced Semiconductor Engineering, Inc., Kaohsiung (TW)

(21) Appl. No.: 16/844,872

(22) Filed: Apr. 9, 2020

(51) Int. Cl. H01L 21/66; H01L 23/00

(52) U.S. Cl. CPC H01L 22/32; H01L 2224/06515; H01L 22/12; H01L 24/06

(57) ABSTRACT

The present disclosure provides a semiconductor device package. The semiconductor device package includes a substrate having a central region and a periphery surrounding the central region, and an electronic component disposed on the substrate. The substrate includes a plurality of testing contacts disposed within the periphery and spaced apart from each other. The electronic component includes a dummy pad. The dummy pad covers two of the plurality of the testing contacts and laterally spaced apart from the other of the plurality of the testing contacts. A method of semiconductor device package alignment inspection is also provided.

### BACKGROUND

### 1. Technical Field

The present disclosure generally relates to a semiconductor device package and a method of semiconductor device package alignment inspection.

### 2. Description of the Related Art

Conductive pillars (for example, copper (Cu) pads, pillars or bumps)) are commonly used as interconnections in semiconductor structures. As the pitch of the conductive pads becomes further reduced to accommodate increasing I/O numbers, it becomes more challenging to inspect the alignment of the interconnections.

### SUMMARY

In one or more embodiments, the present disclosure provides a semiconductor device package. The semiconductor device package includes a substrate having a central region and a periphery surrounding the central region, and an electronic component disposed on the substrate. The substrate includes a plurality of testing contacts disposed within the periphery and spaced apart from each other. The electronic component includes a dummy pad. The dummy pad covers two of the plurality of the testing contacts and laterally spaced apart from the other of the plurality of the testing contacts.

In one or more embodiments, the present disclosure provides a semiconductor device package. The semiconductor device package includes a first substrate having a central region and a periphery surrounding the central region. The semiconductor device package also includes a first testing contact, a second testing contact, and a third testing contact disposed within the periphery of the first substrate and spaced apart from each other. The semiconductor device package also includes a second substrate disposed on the first substrate and a first dummy pad exposed from a surface of the second substrate. The first dummy pad is in contact with the first testing contact and the second testing contact and laterally spaced apart from the third testing contact.

In one or more embodiments, the present disclosure provides a method of semiconductor device package alignment inspection. The method includes providing a first substrate and a second substrate. The first substrate includes a first dummy pad and a second dummy pad, and the second substrate includes a first set of testing contacts adjacent to the first dummy pad and a second set of testing contacts adjacent to the second dummy pad. The method also includes obtaining a first electrical information between the first set of testing contacts and obtaining a second electrical information between the second set of testing contacts. The method also includes determining a relative location between the first substrate and the second substrate based on the first electrical information and the second electrical information.

### BRIEF DESCRIPTION OF THE DRAWINGS

Aspects of the present disclosure are readily understood from the following detailed description when read with the accompanying figures. It should be noted that various features may not be drawn to scale. The dimensions of the various features may be arbitrarily increased or reduced for clarity of discussion.

FIG. 1 is a cross-sectional view of a substrate and an electronic component, in accordance with an embodiment of the present disclosure.

FIG. 2A is a cross-sectional view of a semiconductor device package, in accordance with an embodiment of the present disclosure.

FIG. 2B is a cross-sectional view of a substrate and an electronic component, in accordance with an embodiment of the present disclosure.

FIG. 3A is a top view of an electronic component, in accordance with an embodiment of the present disclosure.

FIG. 3B is a top view of a substrate, in accordance with an embodiment of the present disclosure.

FIG. 4 is a perspective top view of a part of a semiconductor device package, in accordance with an embodiment of the present disclosure.

FIG. 5A is a perspective top view of a part of a semiconductor device package, in accordance with an embodiment of the present disclosure.

FIG. 5B is a cross-sectional view of a part of a semiconductor device package, in accordance with an embodiment of the present disclosure.

FIG. 6 is a flow chart of a semiconductor device package alignment inspection method, in accordance with some embodiments of the present disclosure.

FIG. 7 is a table showing predetermined relative positions of a substrate and an electronic component based on electrical status of the testing contacts, in accordance with some embodiments of the present disclosure.

FIG. 8A illustrates one or more stages of a method of manufacturing a substrate structure in accordance with some embodiments of the present disclosure.

FIG. 8B illustrates one or more stages of a method of manufacturing a substrate structure in accordance with some embodiments of the present disclosure.

FIG. 8C illustrates one or more stages of a method of manufacturing a substrate structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, a reference to the formation of a first feature over or on a second feature in the description that follows may include embodiments in which the first and second features are formed in direct contact, and may also include embodiments in which additional features may be formed between the first and second features, such that the first and second features may not be in direct contact. Besides, the present disclosure may repeat reference numerals and/or letters in the various examples. This repetition is for simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

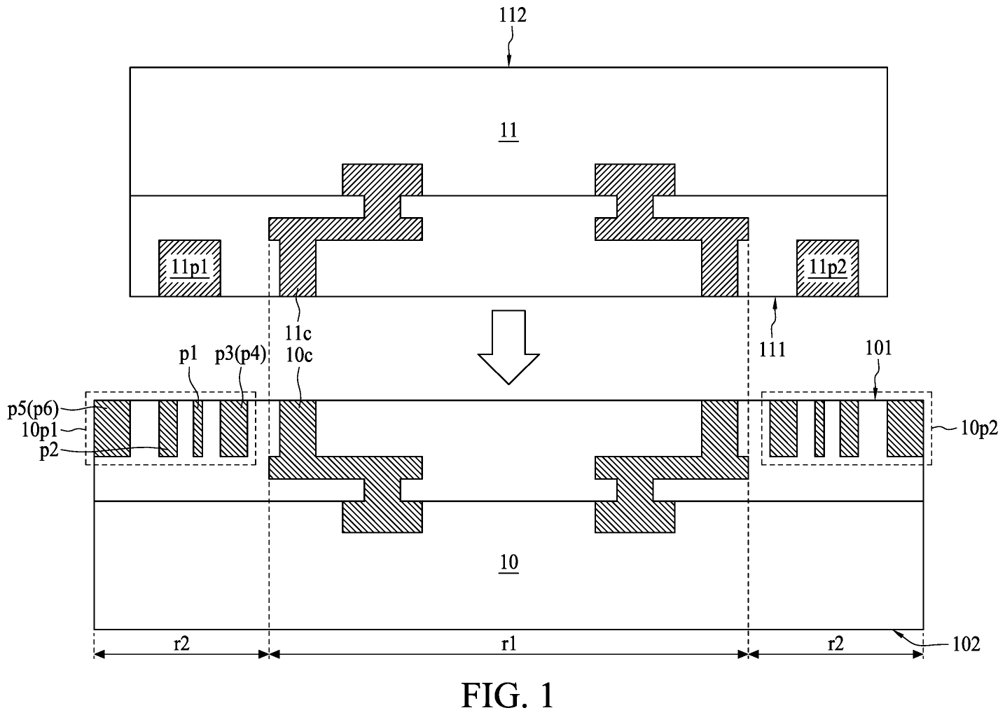

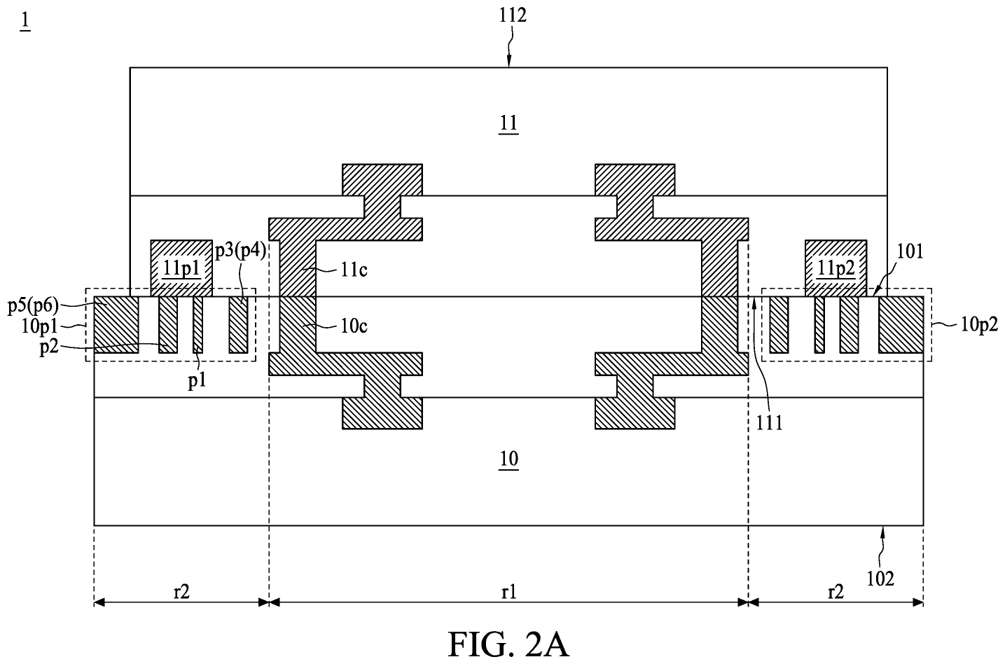

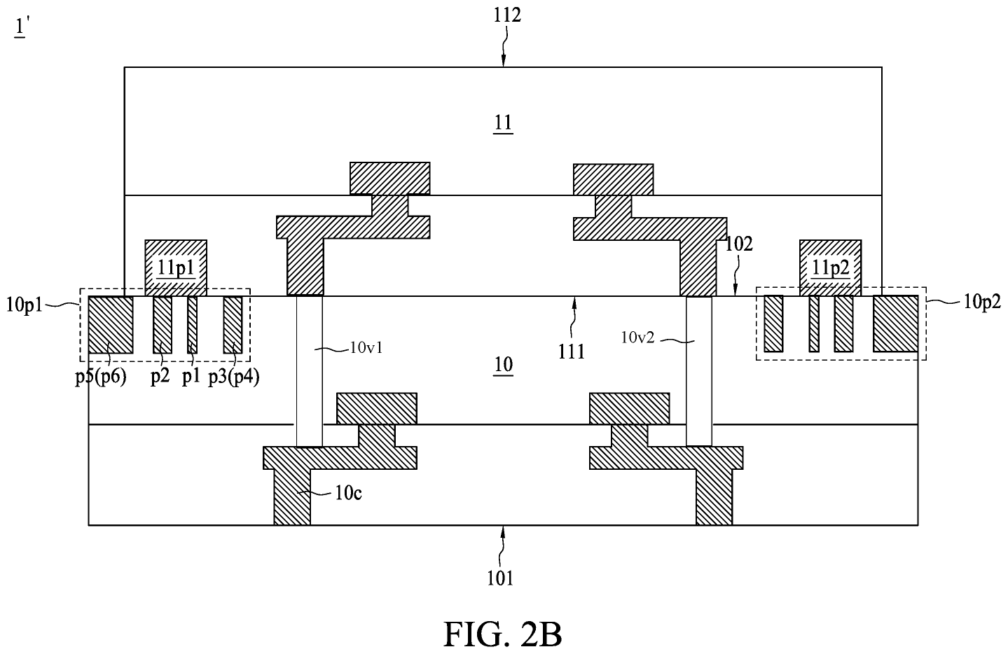

FIG. 1 is a cross-sectional view of a substrate 10 and an electronic component 11, in accordance with an embodiment of the present disclosure. FIG. 2A shows a cross-sectional view after the electronic component 11 is bonded on the substrate 10, forming a semiconductor device package 1.

In some embodiments, the substrate 10 may be, for example, a semiconductor substrate, such as a silicon substrate or another suitable semiconductor substrate. In some embodiments, the substrate 10 may be a semiconductor wafer, such as a silicon wafer, and includes a plurality of semiconductor chips.

The substrate 10 includes a surface 101 and a surface 102 opposite to the surface 101. In some embodiments, the surface 101 is an active surface and the surface 102 is a passive surface or a backside surface. A conductive element 10c and a plurality of testing contacts p1 through p6 (collectively referred to as testing contacts 10p1 and 10p2) may be in proximity to the surface 101, adjacent to the surface 101, embedded in the surface 101, and/or partially exposed from the surface 101. Testing contacts 10p2 (which has a plurality of testing contacts) may be disposed on a diagonal or opposite position with respect to the testing contacts 10p1. For example, the testing contacts 10p1 and the testing contacts 10p2 may be disposed on opposite corners of the substrate 10. Each of the testing contacts 10p2 is not labeled in the figures for conciseness.

The substrate 10 includes an inner region (or a central region, a conducting region) r1 and an outer region (or periphery, a testing region) r2 surrounding the inner region r1. The conductive element 10c is disposed in or within the inner region r1. The testing contacts 10p1 and 10p2 are disposed in or within the outer region r2.

In other words, the conductive element 10c is disposed in the region defined or enclosed by the dotted lines in FIG. 1. The conductive element 10c is surrounded by the testing contacts 10p1 and 10p2.

The conductive element 10c is insulated from the testing contacts 10p1 and 10p2 by, for example, organic material(s) (such as a solder mask, a polyimide (PI), an epoxy, an Ajinomoto build-up film (ABF), a polypropylene (PP), and a bismaleimide triazine (BT)), inorganic material(s) (such as a silicon oxide (SiOₓ), a silicon nitride (SiNₓ), a tantalum oxide (TaOₓ), silicon, a glass, a ceramic, and quartz), or a combination of two or more thereof.

Each of the conductive element 10c and the testing contacts 10p1 and 10p2 may be a conductive pad, a conductive trace, or a conductive pillar. Each of the conductive element 10c and the testing contacts 10p1 and 10p2 may include, for example, gold (Au), silver (Ag), copper (Cu), Nickel (Ni), palladium (Pd), another metal, a solder alloy, or a combination of two or more thereof.

The electronic component 11 may be a chip or a die including a semiconductor substrate, one or more integrated circuit devices and one or more overlying interconnection structures therein.

The electronic component 11 includes a surface 111 facing the substrate 10 and a surface 112 opposite to the surface 111. In some embodiments, the surface 111 is an active surface and the surface 112 is a passive surface or a backside surface. A conductive element 11c and dummy pads 11p1 and 11p2 may be in proximity to the surface 111, adjacent to the surface 111, embedded in the surface 111, and/or partially exposed from the surface 111. The dummy pad 11p1 is disposed in corresponding to the testing contacts 10p1. The dummy pad 11p2 is disposed in corresponding to the testing contacts 10p2. The dummy pad 11p1 may be disposed on a diagonal or opposite position with respect to the dummy pad 11p2. For example, the dummy pad 11p1 and the dummy pad 11p2 may be disposed on opposite corners of the electronic component 11.

Similarly, the electronic component 11 includes an inner region (or a central region, a conducting region) r1 and an outer region (or periphery, a testing region) r2 surrounding the inner region r1. The conductive element 11c is disposed in or within the inner region r1. The dummy pads 11p1 and 11p2 are disposed in or within the outer region r2. In some embodiments, the electronic component 11 may be a semiconductor wafer, such as a silicon wafer, and includes a plurality of semiconductor chips. In such embodiments, the dummy pads 11p1 and 11p2 are disposed in periphery of the semiconductor wafer.

In other words, the conductive element 11c is disposed in the region defined or enclosed by the dotted lines in FIG. 1. The conductive element 11c is surrounded by the dummy pads 11p1 and 11p2. The conductive element 11c is insulated from the dummy pads 11p1 and 11p2.

Each of the conductive element 11c and the dummy pads 11p1 and 11p2 may be a conductive pad, a conductive trace, or a conductive pillar. Each of the conductive element 11c and the dummy pads 11p1 and 11p2 may include the materials as listed above for the conductive element 10c and the testing contacts 10p1 and 10p2.

As shown in FIG. 1, the conductive element 10c and the conductive element 11c to be connected are aligned. After the alignment is done, the electronic component 11 is bonded to or mounted on the substrate 10, forming the semiconductor device package 1 as shown in FIG. 2A.

In FIG. 2A, the substrate 10 and the electronic component 11 (e.g., the conductive element 10c and the conductive element 11c therein) are aligned and connected with each other. For example, the relative position between the substrate 10 and the electronic component 11 is within a design specification. In other words, the relative displacement (such as rotation or shift) between the substrate 10 and the electronic component 11 is within a design specification.

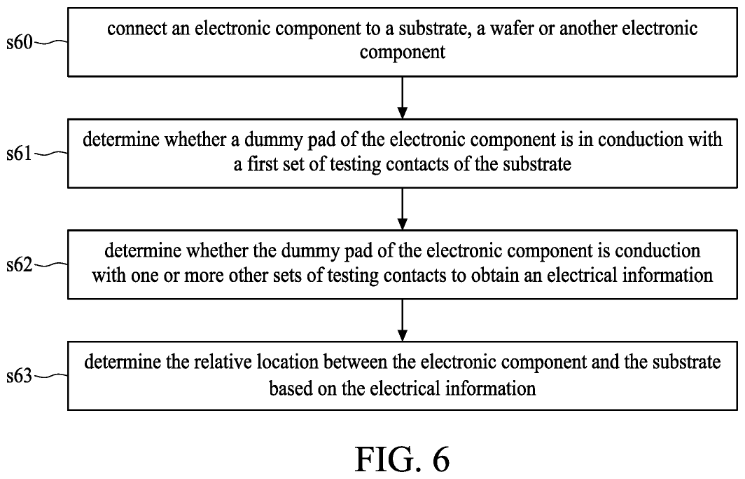

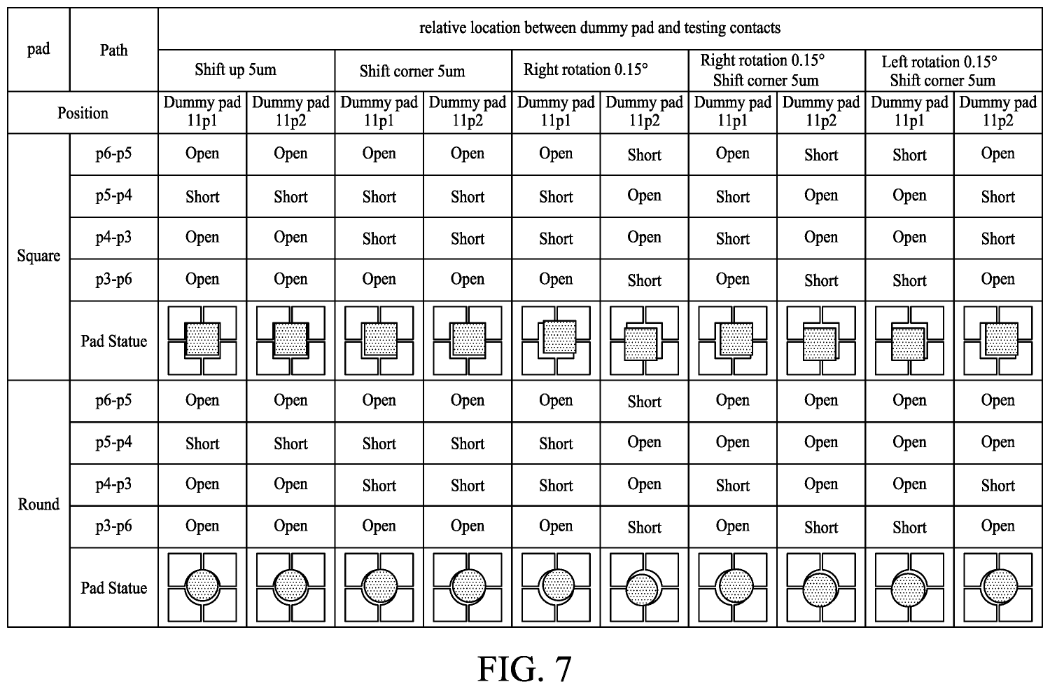

The alignment between the substrate 10 and the electronic component 11 (e.g., the alignment between the conductive element 10c and the conductive element 11c therein) can be inspected by measuring conductivity (such as an open circuit or a short circuit) between the dummy pad 11p1 (or the dummy pad 11p2) and one of the testing contacts p1 through p6; and/or measuring conductivity between two of the testing contacts p1 through p6. The detailed operations and criteria of the alignment inspection method will be described with respect to FIG. 6 and FIG. 7.

As shown in FIG. 2A, when the relative position between the substrate 10 and the electronic component 11 is within a design specification, the dummy pad 11p1 of the electronic component 11 is in contact with the testing contact p1 and the testing contact p2 of the substrate 10 but is not in contact with the testing contacts p3 through p6. For example, the dummy pad 11p1 may be electrically conducted with the testing contact p1 and the testing contact p2 but insulated from the testing contacts p3 through p6. For example, the dummy pad 11p1 is shorted with the testing contact p1 and the testing contact p2 but forms an open circuit with the testing contacts p3 through p6. For example, the testing contacts p3 through p6 are floating.

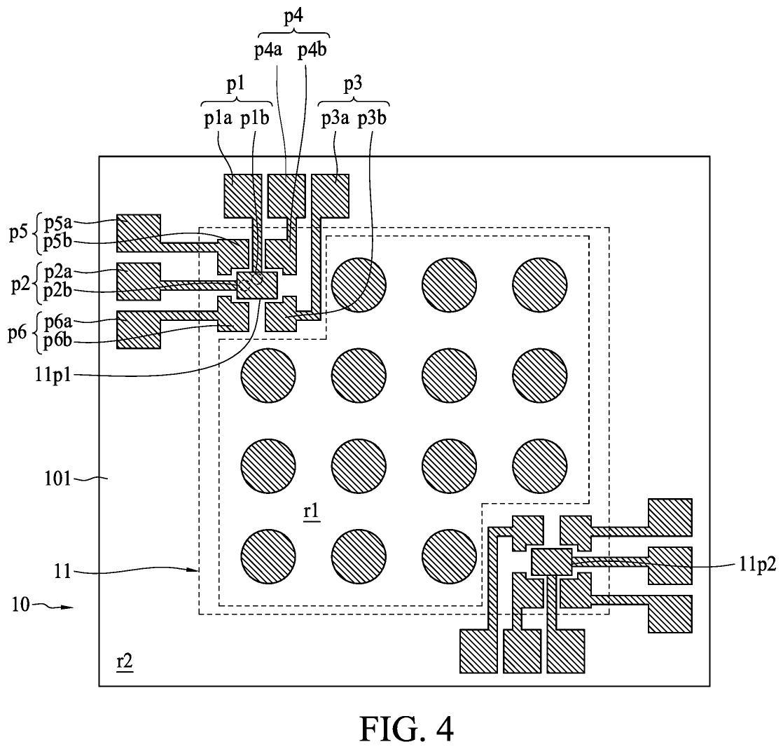

For example, the dummy pad 11p1 covers or overlaps (please refer to FIG. 4) the testing contact p1 and the testing contact p2. For example, the dummy pad 11p1 is laterally spaced apart from the testing contacts p3 through p6. For example, the dummy pad 11p1 is disconnected from the testing contacts p3 through p6.

Similarly, the dummy pad 11p2 of the electronic component 11 is in contact with two of the testing contacts 10p2 of the substrate 10 but is not in contact with the other testing contacts of the testing contacts 10p2.

X-ray or optical microscopes are well-known tools for alignment inspection, but the need for sample preparation is time-consuming and limited resolution may impact the accuracy of displacement information.

An object of the present disclosure is to provide a method allowing accurate alignment inspection and displacement determination. The present disclosure may not require sample preparation, and conductivity (such as open circuit or short circuit) may represent the relative displacement between the substrate and the electronic component. In addition, the method used in the present disclosure is not limited by package size and can detect displacement in micron-scale or nanoscale.

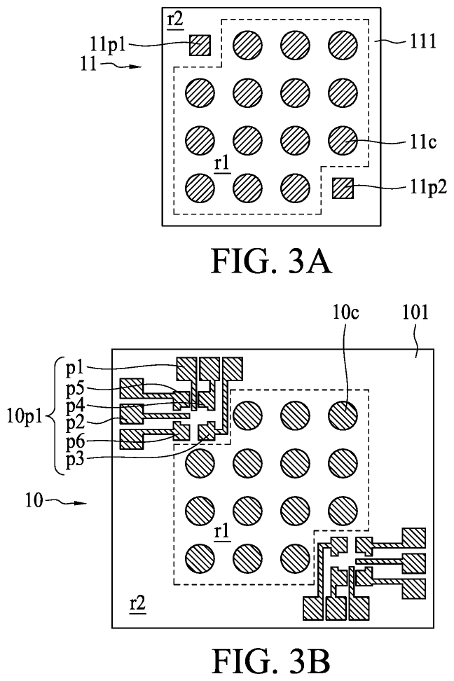

FIG. 3A is a top view of the electronic component 11, in accordance with an embodiment of the present disclosure. FIG. 3B is a top view of the substrate 10, in accordance with an embodiment of the present disclosure. FIG. 4 shows a perspective top view after the electronic component 11 is bonded on the substrate 10. The semiconductor device package 1 in FIG. 2A may be a cross-sectional view of the semiconductor device package in FIG. 4.

As shown in FIG. 4, the testing contacts (such as the testing contacts p1 through p6) are disposed in the periphery of the surface 101 of the substrate 10. The dummy pads 11p1 and 11p2 (which are located at diagonal positions of the surface 111 of the electronic component 11) covers two of the testing contacts (such as the testing contacts p1 and p2).

The testing contact p1 has a portion p1b covered by the dummy pad 11p1 and a portion p1a connected with the portion p1b. The portion p1a is exposed from a projection area of the electronic component 11. Similarly, the testing contact p2 has a portion p2b covered by the dummy pad 11p1 and a portion p2a connected with the portion p2b. The portion p2a is exposed from the electronic component 11. The portion p1b and the portion p2b may form a short circuit if the portion p1b and the portion p2b are in contact with the dummy pad 11p1. The portion p1b and the portion p2b may form an open circuit if at least one of the portion p1b and the portion p2b is not in contact with the dummy pad 11p1. In some embodiments, an electrifying operation may be conducted on the portion p1a and the portion p2a to determine whether the portion p1b and the portion p2b are electrically conducted.

The testing contacts p3 through p6 are spaced apart from the dummy pad 11p1. The testing contacts p3 through p6 surrounds the dummy pad 11p1. The testing contacts p3 through p6 are disposed adjacent to corners of the dummy pad 11p1. The testing contacts p3 through p6 contour the sides of the dummy pad 11p1. Each of the testing contacts p3 through p6 has a portion proximal to the dummy pad 11p1 and a portion distal from the dummy pad 11p1. Take the testing contact p3 for example, the testing contact p3 has a portion p3b and a portion p3a connected with the portion p3b. The portion p3b is overlapped with the projection area of the electronic component 11. The portion p3a is exposed from a projection area of the electronic component 11.

Any two of the testing contacts p3 through p6 may form a short circuit if the two are in contact with the dummy pad 11p1. Similarly, an electrifying operation may be conducted on the portions (such as the portion p3a) exposed from the projection area of the electronic component 11 to determine whether any two of the testing contacts p3 through p6 are electrically conducted.

In some embodiments, the projection area of the dummy pad 11p1 may be different from the projection area of the testing contacts p1, p2, p3, p4, p5, and/or p6. In some embodiments, the projection area of the portion p1a of the testing contact p1 may be substantially similar to the projection area of the portion p1b of the testing contact p1. Similarly, the projection area of the portion p2a of the testing contact p2 may be substantially similar to the projection area of the portion p2b of the testing contact p2. In some embodiments, the projection area of the portion p3a of the testing contact p3 (or the portion p4a of the testing contact p4, the portion p5a of the testing contact p5, the portion p6a of the testing contact p6) may be substantially similar to the projection area of the portion p3b of the testing contact p3 (or the portion p4b of the testing contact p4, the portion p5b of the testing contact p5, the portion p6b of the testing contact p6). In some embodiments, the projection area described above may be substantially parallel to the surface 101 of the substrate 10.

In some embodiments, a separation (or the shortest distance) between the dummy pad 11p1 and one of the testing contacts p1 through p6 may be different from a separation (or the shortest distance) between the dummy pad 11p1 and another one of the testing contacts p1 through p6. For example, the separation between the dummy pad 11p1 and the portion p3b of the testing contact p3 is different from the separation between the dummy pad 11p1 and the portion p4b of the testing contact p4. In some embodiments, the separation described above may be measured in a direction substantially parallel to the surface 101 of the substrate 10.

In some embodiments, the semiconductor device package according to the present disclosure may have any numbers of the dummy pads and the testing contacts according to design requirements and is not limited to the specific embodiments illustrated in the figures. For example, the number of the testing contacts can be N, and N is an integer greater than 1.

Besides, the projection areas, the shapes (such as square or round as shown in FIG. 7), the separations, and the locations of the dummy pads and the testing contacts can be modified according to design requirements and are not limited to the specific embodiments illustrated in the figures.

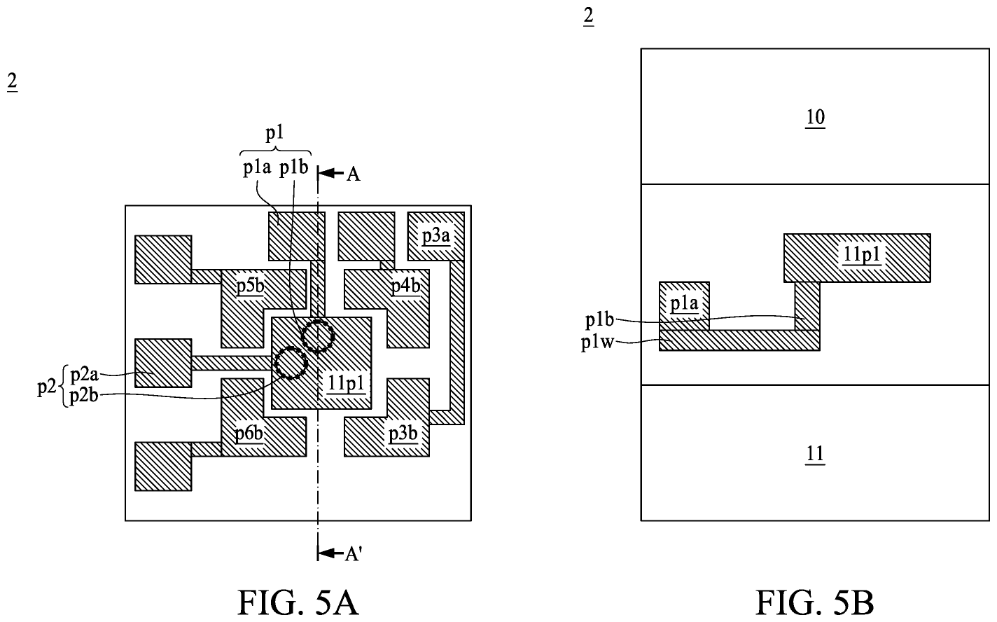

FIG. 5A is a perspective top view of a part of a semiconductor device package 2, in accordance with an embodiment of the present disclosure. The semiconductor device package 2 in FIG. 5B may be a cross-sectional view of the semiconductor device package 2 in FIG. 5A. The semiconductor device package 2 in FIGS. 5A and 5B is similar to the semiconductor device package 1 in FIG. 2A, and the differences therebetween are described below.

In the semiconductor device package 2, the portion p1a and the portion p1b of the testing contact p1 are connected through a trace p1w disposed at an elevation different from the portion p1a and the portion p1b. In some embodiments, the trace p1w may be a part of a redistribution layer (an RDL) or may be formed together with an RDL. In some embodiments, the yield rate of the manufacturing process of the semiconductor device package 2 is higher than that of the semiconductor device package 1.

Referring back to FIG. 2B, FIG. 2B illustrates a cross-sectional view of a semiconductor device package 1′ in accordance with some embodiments of the present disclosure. The semiconductor device package 1′ of FIG. 2B is similar to the semiconductor device package 1 of FIG. 2A, and the differences therebetween is described below.

As shown in FIG. 2B, the surface 102 (which may be a passive surface or a backside surface) of substrate 10 faces the surface 111 (which may be an active surface) of the electronic component 11. The testing contacts 10p1 and 10p2 are disposed in proximity to the surface 102, adjacent to the surface 102, embedded in the surface 102, and/or partially exposed from the surface 102.

The substrate 10 includes a conducive via 10v1 and a conducive via 10v2 electrically connected between the conductive element 10c and the conductive element 11c.

With the structure of semiconductor device package 1′ (in which the substrate 10 faces downwardly), more than two substrates (or electronic components, or wafers, or the combination thereof) can be stacked together. In some embodiments, the testing contacts and the dummy pads can be formed in a structure where more than two substrates (or electronic components, or wafers, or the combination thereof) stacked together, and each of the substrates can face downwardly or upwardly depending on design specifications. In addition, the testing contacts and the dummy pads in each of the substrates can be disposed in proximity to a passive surface or an active surface.

FIG. 6 is a flow chart of a semiconductor device package alignment inspection method, in accordance with some embodiments of the present disclosure. FIG. 7 is a table showing predetermined relative positions of a substrate and an electronic component according to electrical status of the testing contacts, in accordance with some embodiments of the present disclosure.

Referring to operation S60 in FIG. 6, an electronic component is connected to (or bonded to) a substrate (such as bonding the electronic component 11 on the substrate 10 as illustrated in FIG. 1). In some embodiments, the method may be conducted on other structures, such as an electronic component on another electronic component, an electronic component on a wafer, a substrate on a substrate, or other combinations.

Then, the method proceeds to operation s61, determining whether the dummy pad 11p1 of the electronic component 11 is in conduction with (or in contact with) the testing contacts p1 and p2 of the substrate 10. In some embodiments, the determination can be conducted by, for example, electrifying the testing contacts p1 and p2 and detecting the electrical information (such as voltage and/or resistance) and/or the electrical status (e.g., conductivity such as a short circuit or an open circuit) therein. For example, a short circuit between the testing contacts p1 and p2 may represent the conduction between the testing contacts p1 and p2 through the dummy pad 11p1, and thus it can be determined that the dummy pad 11p1 is in conduction with the testing contacts p1 and p2.

Referring to operation s62, the dummy pad 11p1 is detected whether it is insulated from one or more sets of testing contacts of the substrate 10 to obtain one or more electrical information. In some embodiments, the dummy pad 11p1 may be detected whether it is insulated from one or more sets of testing contacts of the substrate 10 located adjacent to the corners the dummy pad 11p1. For example, the dummy pad 11p1 of the electronic component 11 is detected whether it is insulated from the set of the testing contacts p6 and p5 of the substrate 10 (such as insulated from the portions p6b and p5b). In some embodiments, the determination or detection can be conducted by, for example, electrifying the testing contacts p6 and p5 and detecting the electrical information (such as voltage and/or resistance) and/or the electrical status (e.g., conductivity such as a short circuit or an open circuit) therein. An open circuit between the testing contacts p6 and p5 means that the dummy pad 11p1 is insulated from the set of the testing contacts p6 and p5. A short circuit between the testing contacts p6 and p5 means that the dummy pad 11p1 is in conduction with (or in contact with) the set of the testing contacts p6 and p5.

Similar operations may be carried out for other sets of testing contacts. For example, the dummy pad 11p1 of the electronic component 11 can be detected whether it is insulated from the sets of “the testing contacts p5 and p4,” “the testing contacts p4 and p3” and “the testing contacts p3 and p6” of the substrate 10. For example, the dummy pad 11p1 of the electronic component 11 can be detected whether it is insulated from the sets of “the portions p5b and p4b,” “the portions p4b and p3b” and “the portions p3b and p6b” of the substrate 10. In some embodiments, the detection can be carried out between the dummy pad 11p1 of the electronic component 11 and four sets of the testing contacts of the substrate 10. In other embodiments, the detection can be carried out between the dummy pad 11p1 of the electronic component 11 and N sets of the testing contacts depending on different design specifications, and N is an integer equal to or greater than 1.

In some embodiments, similar operations carried out for the dummy pad 11p1 as shown in operations s61 and s62 are performed for the dummy pad 11p2 of the electronic component 11 to obtain one or more electrical information.

Referring to operation s63, the relative location between the electronic component 11 and the substrate 10 is determined (or obtained) based on the electrical information between the dummy pads 11p1, 11p2 of the electronic component 11 and the sets of the testing contacts of the substrate 10.

In some embodiments, if an open circuit is detected between all the sets (such as the testing contacts p3 through p6) of testing contacts for dummy pads 11p1 and 11p2, it is determined that there is no shift or rotation between the electronic component 11 and the substrate 10 or that the shift or rotation between the electronic component 11 and the substrate 10 is within a predetermined value or within the design specification.

In some embodiments, as shown in FIG. 7, in the case that an open circuit is detected between the sets of testing contacts “p6 and p5,” “p4 and p3,” and “p3 and p6” for the dummy pads 11p1 and 11p2, and that an short circuit is detected between the set of the testing contacts “p5 and p4” for the dummy pad 11p1 and 11p2, it is determined that the electronic component 11 shifts upwardly with respect to the substrate 10 about 5 micrometers (μm).

In some embodiments, in the case that an open circuit is detected between the sets of testing contacts “p6 and p5” and “p3 and p6” for the dummy pads 11p1 and 11p2, and that an short circuit is detected between the set of the testing contacts “p5 and p4” and “p4 and p3” for the dummy pad 11p1 and 11p2, it is determined that the electronic component 11 shifts to the upper-right corner with respect to the substrate 10 about 5 μm.

In some embodiments, in the case that an open circuit is detected between the sets of testing contacts “p6 and p5” and “p3 and p6” for the dummy pad 11p1 and between the set of the testing contacts “p5 and p4” and “p4 and p3” for the dummy pad 11p2, and that an short circuit is detected between the set of the testing contacts “p5 and p4” and “p4 and p3” for the dummy pad 11p1 and between the sets of testing contacts “p6 and p5” and “p3 and p6” for the dummy pad 11p2, it is determined that the electronic component 11 rotates in a clockwise direction with respect to the substrate 10 about 0.15 degrees. In some embodiments, it may be determined that the electronic component 11 rotates in a clockwise direction with respect to the substrate 10 about 0.15 degrees and shifts to the bottom-right corner with respect to the substrate 10 about 5 μm.

In some embodiments, in the case that an open circuit is detected between the set of the testing contacts “p5 and p4” and “p4 and p3” for the dummy pad 11p1 and between the sets of testing contacts “p6 and p5” and “p3 and p6” for the dummy pad 11p2, and that an short circuit is detected between the sets of testing contacts “p6 and p5” and “p3 and p6” for the dummy pad 11p1 and between the set of the testing contacts “p5 and p4” and “p4 and p3” for the dummy pad 11p2, it is determined that the electronic component 11 rotates in an anticlockwise direction with respect to the substrate 10 about 0.15 degrees. In some embodiments, it may be determined that the electronic component 11 rotates in an anticlockwise direction with respect to the substrate 10 about 0.15 degrees and shifts to the bottom-right corner with respect to the substrate 10 about 5 μm.

For the relative location between the electronic component 11 and the substrate 10 in the case that the dummy pads 11p1 and 11p2 are round, please refer to FIG. 7.

In some embodiments, the relative displacements of the electronic component (such as shift upward/downward, shift to a corner, rotate in a clockwise/anti clockwise direction) in micron-scale or nanoscale with respect to the substrate can be detected through the method used in the present disclosure. It is to be noticed that some of the relative displacements are omitted in the table of FIG. 7 for conciseness, and the present disclosure is not limited to the specific relative displacements illustrated in the table of FIG. 7.

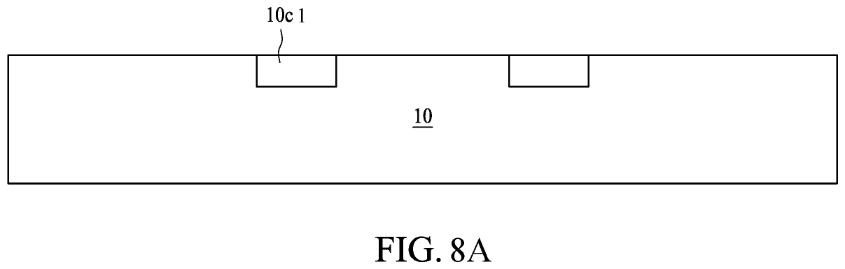

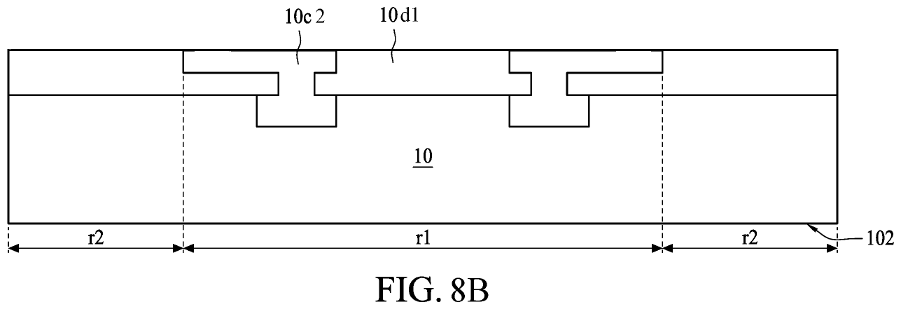

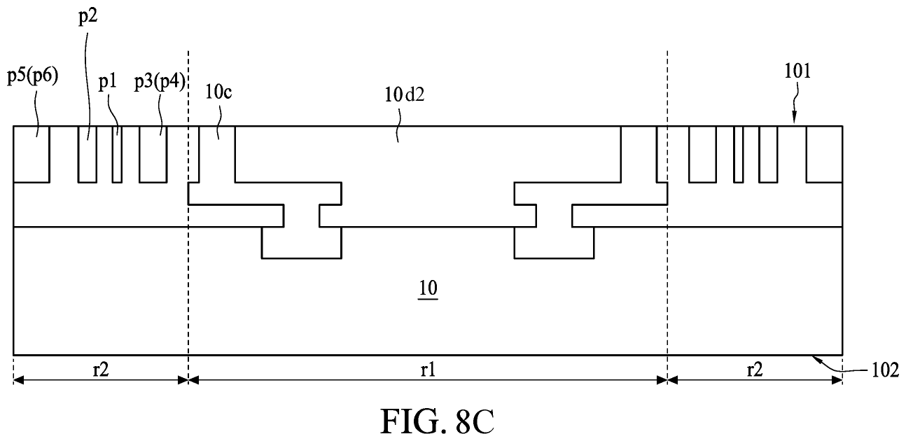

FIG. 8A, FIG. 8B, and FIG. 8C are cross-sectional views of a semiconductor device package at various stages of fabrication, in accordance with some embodiments of the present disclosure. At least some of these figures have been simplified for a better understanding of the aspects of the present disclosure.

Referring to FIG. 8A, a substrate 10 is provided. The substrate 10 includes a conductive element 10c1 provided in proximity to and at least partially exposed from a surface of the substrate 10. In the present embodiment, the substrate 10 may include several units that one may be separable from another by a scribe line. Since each of the units is subjected to similar or identical processes in the manufacturing method, for convenience, only an exemplary unit is illustrated and described in the following description.

Referring to FIG. 8B, a dielectric layer 10d1 is disposed on the substrate 10 to cover the conductive element 10c1 as shown in FIG. 8A. The dielectric layer 10d1 can be disposed by, for example, coating, lamination, chemical vapor deposition (CVD) or other suitable processes. The dielectric layer 10d1 can be patterned through a photoresist film (or a mask) by, for examples, lithographic technique, to expose a portion of the conductive element 10c1 as shown in FIG. 8A. Conductive materials may be disposed on the exposed portion of the conductive element 10c1 by, for examples, sputtering, electroless plating, printing, or other suitable processes, forming a conductive element 10c2 as shown in FIG. 8B. In some embodiments, after disposing the conductive materials, a planarization operation, such as a chemical-mechanical polishing (CMP) operation may be performed. In some embodiments, the conductive element 10c2 may be an RDL. As shown in FIG. 8B, the conductive element 10c2 is disposed in an inner region (or a central region, a conducting region) r1 enclosed by the dotted lines.

Referring to FIG. 8C, a dielectric layer 10d2 is disposed on the dielectric layer 10d1 to cover the conductive element 10c2 as shown in FIG. 8B. Similar operations may be conducted to pattern the dielectric layer 10d2 and forming a conductive element 10c, and testing contacts p1 through p6. The testing contacts p1 through p6 are insulated from the conductive element 10c by the dielectric layer 10d2.

In some embodiments, a singulation operation (e.g., by using a dicing saw, laser, punching machine or other appropriate cutting technique) may be conducted to cut out discrete substrate as illustrated in FIG. 1.

In some embodiments, similar operations may be performed for the electronic component 11 as illustrated in FIG. 1 to form the dummy pads 11p1 and 11p2.

Spatially relative terms, such as “beneath,” “below,” “lower,” “above,” “upper,” “left,” “right” and the like, may be used herein for ease of description to describe one element or feature's relationship to another element(s) or feature(s) as illustrated in the figures. The spatially relative terms are intended to encompass different orientations of the device in use or operation, in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately”, “substantially”, “substantial” and “about” are used to describe and account for small variations. When used in conduction with an event or circumstance, the terms can refer to instances in which the event or circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints unless specified otherwise. The term “substantially coplanar” can refer to two surfaces within micrometers (μm) of lying along the same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

1. A semiconductor device package, comprising:
a substrate having a central region and a periphery surrounding the central region, the substrate including a plurality of testing contacts disposed within the periphery and spaced apart from each other; and
an electronic component disposed on the substrate, the electronic component including a dummy pad;
wherein the dummy pad covers two of the plurality of the testing contacts and laterally spaced apart from the other of the plurality of the testing contacts.

2. The semiconductor device package as claimed in claim 1, wherein the other of the plurality of the testing contacts surrounds the dummy pad.

3. The semiconductor device package as claimed in claim 1, wherein a projection area of the dummy pad is different from a projection area of at least one of the plurality of the testing contacts.

4. The semiconductor device package as claimed in claim 1, wherein a separation between the dummy pad and one of the plurality of the testing contacts is different from a separation between the dummy pad and another of the plurality of the testing contacts.

5. The semiconductor device package as claimed in claim 1, wherein at least one of the plurality of the testing contacts includes a first portion and a second portion connecting with the first portion, wherein the first portion is proximal to the dummy pad and the second portion is distal from the dummy pad.

6. The semiconductor device package as claimed in claim 5, wherein the second portion is at least partially exposed from a projected area of the electronic component.

7. The semiconductor device package as claimed in claim 5, wherein the first portion and the second portion are connected through a trace disposed at an elevation different from the first portion and the second portion.

8. A semiconductor device package, comprising:
a first substrate having a central region and a periphery surrounding the central region;
a first testing contact, a second testing contact, and a third testing contact disposed within the periphery of the first substrate and spaced apart from each other;
a second substrate disposed on the first substrate; and
a first dummy pad exposed from a surface of the second substrate;
wherein the first dummy pad is in contact with the first testing contact and the second testing contact and laterally spaced apart from the third testing contact.

9. The semiconductor device package as claimed in claim 8, wherein the third testing contact surrounds a part of the first dummy pad.

10. The semiconductor device package as claimed in claim 8, wherein the third testing contact includes a first portion and a second portion connecting with the first portion of the third testing contact, wherein the second portion of the third testing contact is at least partially exposed from a projected area of the second substrate.

11. The semiconductor device package as claimed in claim 8, further comprising a fourth testing contact, a fifth testing contact and a sixth testing contact spaced apart from each other, wherein the first dummy pad is laterally spaced apart from the fourth testing contact, the fifth testing contact, and the sixth testing contact.

12. The semiconductor device package as claimed in claim 11, wherein the third testing contact, the fourth testing contact, the fifth testing contact, and the sixth testing contact surround the first dummy pad.

13. The semiconductor device package as claimed in claim 8, wherein the first testing contact includes a first portion in contact with the first dummy pad and a second portion connecting with the first portion of the first testing contact, wherein the second portion of the first testing contact is at least partially exposed from a projected area of the second substrate.

14. The semiconductor device package as claimed in claim 8, further comprising a second dummy pad exposed from the surface of the second substrate, wherein the first dummy pad and the second dummy pad are disposed on diagonal positions of the second substrate.

15. The semiconductor device package as claimed in claim 8, further comprising a conductive element disposed within the central region of the first substrate, wherein the conductive element is insulated from the first testing contact.

16. The semiconductor device package as claimed in claim 15, wherein the third testing contact is between the first testing contact and the conductive element.

17-20. (canceled)

21. The semiconductor device package as claimed in claim 1, wherein the dummy pad is exposed from a surface of the electronic component facing the substrate.

22. The semiconductor device package as claimed in claim 1, wherein the dummy pad is insulated from the other of the plurality of the testing contacts.

23. The semiconductor device package as claimed in claim 6, wherein the first portion is in contact with the dummy pad.

24. The semiconductor device package as claimed in claim 10, wherein the first portion and the second portion of the third testing contact are non-overlapping with the first dummy pad in a direction substantially perpendicular to the surface of the second substrate.
